(19) United States
(12) Patent Application Publication
(10) Pub. No.: US 2006/0278953 A1
(43) Pub. Date: Dec. 14, 2006

(54) SEMICONDUCTOR MEMORY DEVICE

(75) Inventor: Wataru SHIMIZU, Miyagi (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/423,155

(22) Filed: Jun. 9, 2006

(30) Foreign Application Priority Data
Jun. 14, 2005 (JP) 2005-173350

(51) Int. Cl. H01L 29/00

(52) U.S. Cl. 257/529

(57) ABSTRACT

A semiconductor device comprises a lower substrate, an interlayer insulation film formed on the lower substrate, a first wiring pattern having a first wiring layer formed on the lower substrate, a first fuse formed on the interlayer insulation film, and a first contact plug electrically connected between the first wiring layer and first fuse; and a second wiring pattern having a second wiring layer, a second fuse formed on the interlayer insulation film, and a second contact plug electrically connected between the second wiring layer and the second fuse. The second fuse has a region which does not overlap with the first fuse in a width direction, the second wiring pattern is separated from the first wiring pattern by a predetermined distance, and the first fuse has a region which does not overlap with the second fuse in a width direction.

### BACKGROUND OF THE INVENTION

1. Field of the Invention

The present invention relates to a semiconductor memory device, particularly to the structure of a redundancy fuse in a semiconductor memory device.

2. Background Information

In recent years, in response a growing need for highly integrated LSI (large scale integration) circuits, fine processing technology such as photolithography and etching has been developed. Along with it, it has become necessary to have appropriate size (position) control with higher precision in the post-wafer processes, such as a probing (operation check) process, chip cutting, packaging processes, and the like.

In particular, with respect to a semiconductor memory device highly integrated to the extent of more than 128 Mbit (megabits), which has become mainstream in recent years, the rate of defective memory cells (i.e., memory cells which might cause operational defects) included per chip has increased, and therefore, it is difficult to have all bits operate without defects.

One technology for inhibiting a reduction in yield ratio due to the presence of defective memory cells is a technology using redundant memory cells (which are also called spare cells). In this technology, the redundant memory cells are previously formed in addition to the necessary number of bits, and in the event there are defective memory cells, these redundant memory cells will be used instead of the defective memory cells to satisfy the necessary number of bits.

One type of technology for replacing defective cells with redundant memory cells is a technology that uses a laser repairing technique (e.g. Laid-Open Japanese Patent Application No. 2000-114382 (hereinafter to be referred to as patent reference 1)). In this technology, portions of the wiring which select the addresses of defective bits are irradiated with laser beams so as to be fused by the heat energy generated by the laser irradiation. By this process, reading or writing with respect to the addresses of the defective bits will become impossible. A semiconductor memory device using this technology will have a circuit structure such that the redundant memory cells will be selected instead of the memory cells in which reading or writing is disabled, in situations in which the addresses corresponding to the fused wiring portions are selected.

In the above structure, sizes such as the intervals and widths of the wiring portions to be fused by the laser beams (hereinafter these wiring portions are to be referred to as fuses) will be determined based on various factors such as the irradiating position accuracy of the laser beam, variation in the laser spot, variation in the thickness of an upper layer protective film covering the fuse, and so forth.

Since the technology that uses this type of laser repairing technique can apply accumulated conventional know-how, it is particularly used in devices such as general-purpose DRAM (dynamic random access memory), which must be produced at low cost.

Patent reference 1 discloses technology that uses a dummy wiring in order to prevent damages that can be caused on a wiring or element in a layer underneath a fuse, at the time of laser irradiation.

In the meantime, in recent years, in accordance with further developments in high integration of memory devices, wirings such as fuses must be arranged at higher density. However, since the upper and lower limits of widths of the fuses and the distance between each two adjacent fuses are determined based on the processing precision of the device conducting the laser repairing process (hereinafter such device will be referred to as a laser repairing device), there will be certain limits to which the fuses can be arranged at a high density.

For instance, when the width of a fuse is smaller than the lower limit, there is a possibility that the fuse will not be fused accurately due to constraints with respect to the precision of the laser irradiation position. On the other hand, when the width of a fuse is larger than the upper limit, there is a possibility that the fuse will not be fused accurately due to constraints with respect to the spot diameter of a laser beam to be used. Moreover, when the distance between two adjacent fuses is smaller than the lower limit, there is a possibility that other fuses adjacent to the fusing target fuses might be fused by the laser beam at the time of fusing and the heat energy generated by the fusing.

In the meantime, in order to be able to redress a large number of memory cells using the redundant memory cells, a semiconductor memory device has to carry a large number of fuses. If the ratio of salvable memory cells is small, all the defective memory cells might not be redressed. Accordingly, there is a possibility that the yield ratio of the product might decrease.

Therefore, according to the conventional technology, there are two contradictory conditions: (1) a large number of fuses are needed in order to redress a large number of memory cells, and (2) there is a limit with respect to arranging the fuses at a high density due to the constraints with respect to the processing precision of the laser repairing device.

In view of the above, it will be apparent to those skilled in the art from this disclosure that there exists a need for an improved semiconductor memory device. This invention addresses this need in the art as well as other needs, which will become apparent to those skilled in the art from this disclosure.

### SUMMARY OF THE INVENTION

It is therefore an object of the present invention to resolve the above-described problems and to provide a semiconductor memory device which is capable of having a number of fuses that can be arranged at high density.

In accordance with one aspect of the present invention, a semiconductor device comprises a lower substrate, an interlayer insulation film formed on the lower substrate, a first wiring pattern having a first wiring layer formed on the lower substrate, a first fuse formed on the interlayer insulation film, and a first contact plug electrically connected between the first wiring layer and first fuse; and a second wiring pattern having a second wiring layer, a second fuse formed on the interlayer insulation film, and a second contact plug electrically connected between the second wiring layer and the second fuse. The second fuse has a region which does not overlap with the first fuse in a width direction, the second wiring pattern is separated from the first wiring pattern by a predetermined distance, and the first fuse has a region which does not overlap with the second fuse in a width direction.

In accordance with another aspect of the present invention, a semiconductor device comprises a lower substrate, an interlayer insulation film formed on the lower substrate, a first wiring pattern having a first wiring layer formed on the lower substrate, a first fuse formed on the interlayer insulation film, and a first contact plug electrically connected between the first wiring layer and first fuse; and a second wiring pattern having a second wiring layer, a second fuse formed on the interlayer insulation film, and a second contact plug electrically connected between the second wiring layer and the second fuse. The second fuse does not overlap with the first fuse in a width direction, and the second wiring pattern is separated from the first wiring pattern by a predetermined distance.

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is a schematic block diagram showing an outline structure of a semiconductor memory device according to a first embodiment of the present invention;

FIG. 2 is a plan view showing a layer structure of the semiconductor memory device according to the first embodiment of the present invention;

FIG. 3A is a sectional view of the semiconductor memory device according to the first embodiment of the present invention shown in FIG. 2 taken along line I-I′;

FIG. 3B is a sectional view of the semiconductor memory device according to the first embodiment of the present invention shown in FIG. 2 taken along line II-II′;

FIG. 4 is a sectional view of the semiconductor memory device according to the first embodiment of the present invention shown in FIG. 2 taken along line III-III′;

FIG. 5A is a plan view showing a layout of fuses as a comparative example 1;

FIG. 5B is a sectional view of the layout shown in FIG. 5A taken along line IV-IV′;

FIG. 6A is a plan view showing a layout of fuses as a comparative example 2;

FIG. 6B is a sectional view of the layout shown in FIG. 6A taken along line V-V′;

FIG. 7 is a plan view showing scales in the layer structure of the semiconductor memory device according to the first embodiment of the present invention;

FIG. 8 is a plan view showing a layer structure of a modified semiconductor memory device according to the first embodiment of the present invention;

FIG. 9 is a plan view showing a layer structure of a semiconductor memory device according to a second embodiment of the present invention;

FIG. 10A is a sectional view of the semiconductor memory device according to the second embodiment of the present invention shown in FIG. 9 taken along line VI-VI′;

FIG. 10B is a sectional view of the semiconductor memory device according to the second embodiment of the present invention shown in FIG. 9 taken along line VII-VII′;

FIG. 11 is a sectional view of the semiconductor memory device according to the second embodiment of the present invention shown in FIG. 9 taken along line VIII-VIII′; and

FIG. 12 is a plan view showing scales in the layer structure of the semiconductor memory device according to the second embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### Embodiment 1

First, a first embodiment of the present invention will be described in detail with reference to the drawings. This embodiment will show the structure of a semiconductor memory device in which, in a certain wiring pattern including a fuse, at least a portion thereof adjacent to laser irradiation regions in other wiring patterns is moved to the lower layer in the layer structure.

Structure

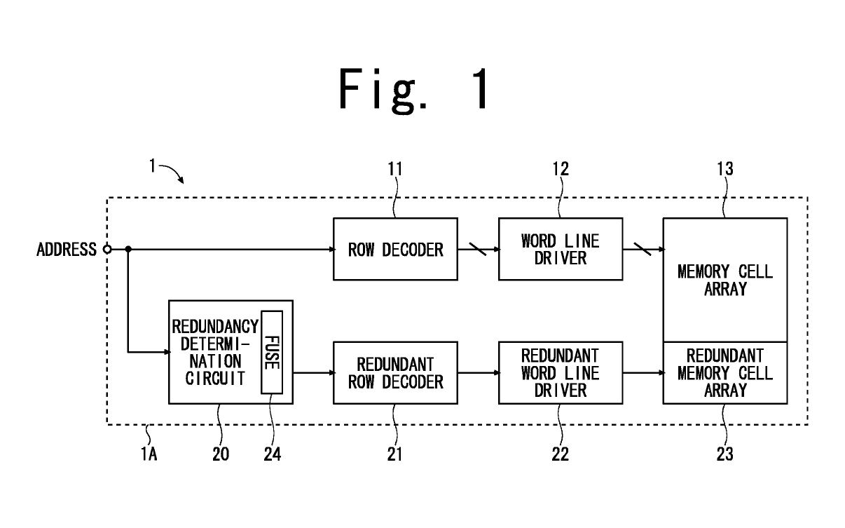

FIG. 1 is a schematic block diagram showing an outline structure of a semiconductor memory device 1 according to the first embodiment of the present invention. As shown in FIG. 1, the semiconductor memory device 1 has a row decoder 11, a word line driver 12, a memory cell array 13, a redundancy determination circuit 20, a redundant row decoder 21, a redundant word line driver 22, and a redundant memory cell array 23. Here, the row decoder 11, the word line driver 12, the memory cell array 13, the redundancy determination circuit 20, the redundant row decoder 21, the redundant word line driver 22, and the redundant memory cell array 23 are formed on the same semiconductor chip 1A, for instance.

In the above structure, an address outputted by an external circuit that is not shown (e.g. a CPU (central processing unit)) will be inputted to the row decoder 11 and the redundancy determination circuit 20.

Upon receiving the address, the row decoder 11 will decode the address. Then the row decoder 11 will generate an enable signal in order to drive a word line corresponding to the decoded address (hereinafter this enable signal will be referred to as a first enable signal), and output the first enable signal to the word line driver 12. Upon receiving the first enable signal, the word line driver 12 will let the word line corresponding to the address rise at a predetermined potential. Thereby, reading or writing of data with respect to a predetermined memory cell (i.e., a memory cell designated by the address) in the memory cell array 13 will become possible.

The redundancy determination circuit 20 is a circuit for determining whether or not a redundant memory cell should be used based on the inputted address, and it includes a fuse portion 24 (which is equivalent to an upper fuse 204 to be described below) corresponding one-to-one with a word line in the redundant memory cell array 23 (hereinafter this word line will be referred to as a redundant word line). Here, a redundant word line selects a redundant memory cell among other redundant memory cells in the redundant memory cell array 23 which will be described below.

To this redundancy determination circuit 20, an address corresponding to a word line selecting a defective memory cell included in the memory cell array 13 is programmed in advance using a fuse. Upon receiving the address from the external circuit, the redundancy determination circuit 20 will compare the inputted address with the programmed address, and when the two addresses coincide with each other, the redundancy determination circuit 20 will generate an enable signal in order to enable a redundant memory cell to be used (hereinafter this enable signal will be referred to as a second enable signal), and output the second enable signal to the redundant row decoder 21.

Upon receiving the second enable signal, the redundant row decoder 21 will generate an enable signal in order to drive a word line selecting the redundant memory cell (hereinafter this enable signal will be referred to as a third enable signal), and output the third enable signal to the redundant word line driver 22. In response to the input of the third enable signal, the redundant word line driver 22 will let the word line (i.e., the redundant word line) selecting the redundant memory cell rise at a predetermined potential. Thereby, reading or writing of data with respect to a predetermined redundant memory cell (i.e., a redundant memory cell replacing the defective memory cell) in the redundant memory cell array 23 will become possible.

Sectional Structure

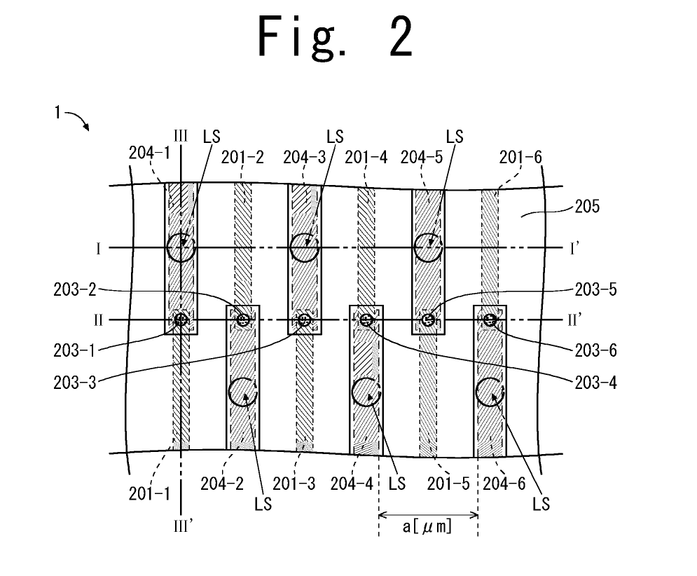

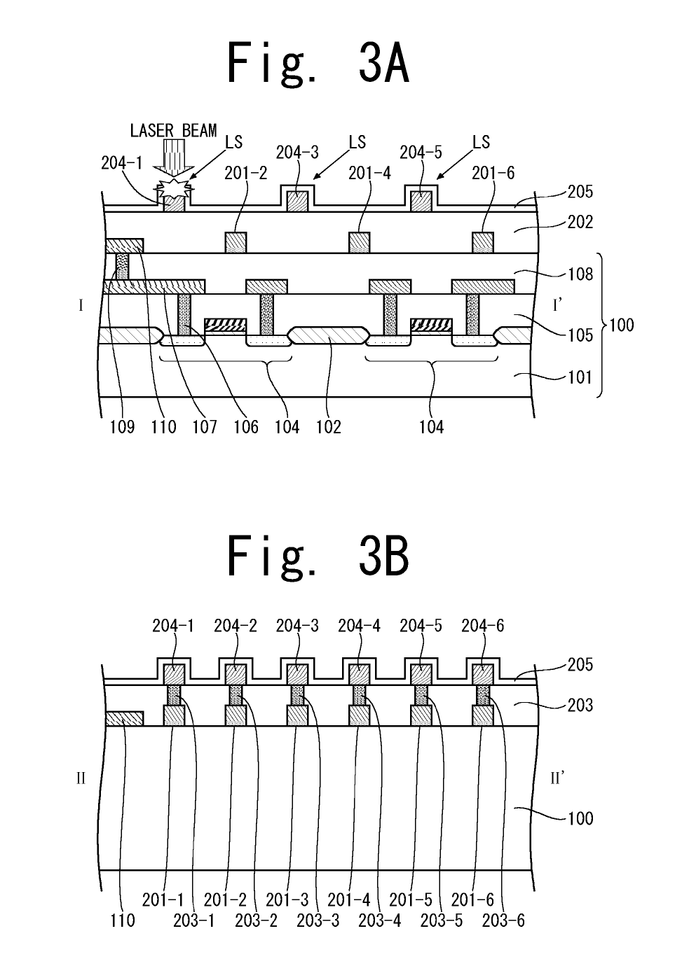

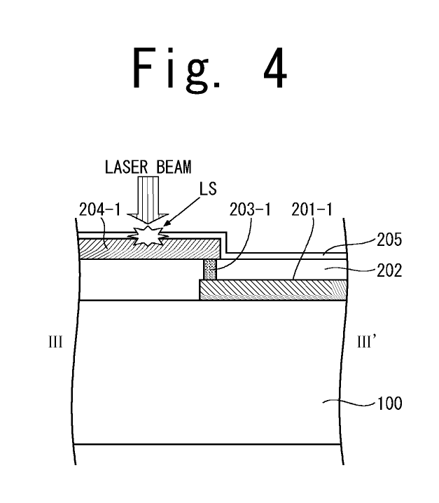

Now, the layer structure of the semiconductor memory device 1 according to the first embodiment of the present invention will be described in detail with reference to the drawings. FIG. 2 is a plan view showing the layer structure of the semiconductor memory device 1, and shows a portion extracted from a region where fuses are arranged (i.e., a portion corresponding to the fuse portion 24 of the redundancy determination circuit 20 shown in FIG. 1). FIG. 3A is a sectional view of the semiconductor memory device 1 shown in FIG. 2 taken along line I-I′, FIG. 3B is a sectional view of the semiconductor memory device 1 shown in FIG. 2 taken along line II-II′, and FIG. 4 is a sectional view of the semiconductor memory device 1 shown in FIG. 2 taken along line III-III′. In FIG. 3B and FIG. 4, the structure of a lower substrate 100 shown in FIG. 3A is shown in a simplified form.

As shown in FIG. 3A, FIG. 3B and FIG. 4, the semiconductor memory device 1 has a lower substrate 100, a wiring layer 110 formed on the lower substrate 100, a lower wiring layers (i.e., first and second wiring layers) 201-1 to 201-6, . . . (hereinafter an arbitrary lower wiring layer will be referred to as a lower wiring layer 201) also formed on the lower substrate 100, an interlayer insulation film 202 formed so as to bury the lower wiring layer 201, upper fuses (i.e., first and second fuses) 204-1 to 204-6, . . . (hereinafter an arbitrary upper fuse will be referred to as an upper fuse 204) formed on the interlayer insulation film 202, contact plugs (i.e., first and second contact plugs) 203-1 to 203-6, . . . (hereinafter an arbitrary contact plug will be referred to as a contact plug 203) electrically connecting the lower wiring layers 201 and the upper fuses 204, and an upper layer protection film 205 covering the upper fuses 204.

In the above structure, the lower wiring layer 201 and the upper fuse 204 correspond to each other, and by having them electrically connected via the contact plug 203 as shown in FIG. 3B and FIG. 4, one wiring pattern (first/second wiring) is formed. For instance, the lower wiring layer 201-1 and the upper fuse 204-1 correspond to each other, and by having them electrically connected via the contact plug 203-1, one wiring pattern is formed.

As shown in FIG. 3A, the lower substrate 100 has a semiconductor substrate 101, element separating insulation films 102, transistors 104 formed in the regions defined by the element separating insulation films 102 and active regions, an interlayer insulation film 105 formed on the semiconductor substrate 101 so as to bury the transistors 104, wiring layers 107 formed on the interlayer insulation film 105, contact plugs 106 formed in the interlayer insulation film 105 such that diffusion regions (i.e., source/drain regions) in the transistors 104 and the wiring layers 107 are electrically connected, an interlayer insulation film 108 formed on the interlayer insulation film 105 so as bury the wiring layers 107, and contact plugs 109 formed in the interlayer insulation film 108 such that the wiring layers 107 and wiring layers 110 formed on the interlayer insulation film 108 are electrically connected.

As mentioned above, the wiring layers 110 and the lower wiring layers 201 are formed on the lower substrate 100. The wiring layer 110 and the lower wiring layer 201 are conductive films made of, for example, polysilicon (Poly-Si), polycide (e.g., tungsten polycide (WSi/Poly-Si)), etc. This type of wiring layer 110 and lower wiring layer 201 can be formed using a known patterning technology (i.e., photolithography and etching), for instance. Here, the surface of the interlayer insulation film 108 where the wiring layers 110 and the lower wiring layers 201 are formed should preferably be planarized using CMP (chemical and mechanical polishing), for instance. Furthermore, the wiring layer 110 and the lower wiring layer 201 may be electrically connected.

The wiring layer 110 and the lower wiring layer 201 formed on the interlayer insulation film 108 are buried in the intermediate insulation layer 202. In other words, the interlayer insulation film 202 is formed on the interlayer insulation film 108 to a thickness sufficient to bury the wiring layer 110 and the lower wiring layer 201. This interlayer insulation film 202 is a type of insulation film formed by depositing silicon oxide (SiOx) using a CVD (chemical vapor deposition) method, for instance. Here, the surface of the interlayer insulation film 202 should preferably be planarized using a CMP method, for instance.

In the interlayer insulation film 202, multiple openings are formed corresponding with the positions of the lower wiring layers 201 by using known photolithography and etching processes. These openings are filled up with a conductive material such as tungsten (W), copper (Cu), or the like, to become the contact plugs 203. The contact plugs 203 are formed by filling the openings with tungsten (W), etc. using a CVD method or filling the openings with copper (Cu), etc. using a plating method, for instance.

On the interlayer insulation film 202, the upper fuses 204 are formed corresponding with the positions of the contact plugs 203. These upper fuses 204 are conductive films made of polysilicon, polycide, etc., for instance, and can be formed using a known patterning technology (i.e., photolithography and etching).

The upper fuses 204 formed in the above described way are covered with the upper layer protection film 205. This upper layer protection film 205 is also formed on the exposed portions of the interlayer insulation film 202. The upper layer protection film 205 is a type of insulation film formed as a P-TEOS (i.e., plasma TEOS) film using a plasma CVD method, for instance, and it functions as a film for protecting the upper fuses 204 from dust, dirt, physical or electrical damage, laser beams irradiating other upper fuses 204, and the heat energy generated by the laser irradiation. The upper layer protection film 205 should be adjusted to an appropriate thickness such that a laser beam can easily reach the wiring and such that the wiring melted by the heat energy may be easily dispersed, when the laser repairing method is used.

In the above structure, the wiring pattern including the lower wiring layer 201, the upper fuse 204, and the contact plug 203 constitutes the fuse portion 24 contained in the redundancy determination circuit 20 shown in FIG. 1. This type of wiring pattern is formed as a part of a wiring that connects a circuit (not shown) provided in the redundancy determination circuit 20 in order to determine whether or not redressing is necessary, with the redundant row decoder 21 disposed at a subsequent level of the redundancy determination circuit 20.

Layout of Wiring Patterns

Now, with reference to FIG. 2 to FIG. 4, the layout of wiring patterns which each include the lower wiring layer 201, the upper fuse 204, and the contact plug 203 will be described. In FIG. 2, in order to be able to clearly show the structure, the width of the upper fuse 204 (in the horizontal direction of the drawing) is made thicker than the width of the lower wiring layer 201. However, this is not a limiting condition in the present invention, and it is also possible to have the widths of the upper fuse 204 and the lower wiring layer 201 be approximately the same or the width of the lower wiring layer 201 be smaller or wider than the width of the upper fuse 204.

As described with reference to FIG. 3A, FIG. 3B and FIG. 4, each individual wiring pattern has a structure in which the lower wiring layer 201 formed on the lower substrate 100 (i.e., a lower layer) and the upper fuse 204 formed on the interlayer insulation film 202 (i.e., an upper layer) are connected via the contact plug 203 formed within the interlayer insulation film 202. This is a structure in which, in a certain wiring pattern, at least a portion thereof adjacent to laser irradiation regions LS in other wiring patterns is moved to the lower layer in the layer structure.

In the layout example shown in FIG. 2, laser irradiation regions LS are arranged perpendicular to the direction (i.e., the vertical direction in FIG. 2) in which the wiring patterns extend (i.e., the laser irradiation regions LS are arranged in the horizontal direction in FIG. 2) in two upper and lower rows in the drawing. The irradiation regions LS in the wiring patterns are alternately arranged on the upper and lower portions of the wiring patterns in the drawing. In addition, the upper fuses 204 in the wiring patterns are also alternately arranged on the upper and lower portions of the wiring patterns in a zigzag configuration. Therefore, considering an irradiation region LS of a certain upper fuse 204 in a certain wiring pattern, an upper fuse 204 arranged immediately adjacent to this irradiation region LS in a width direction will not be the irradiation region LS on the immediately adjacent wiring pattern but rather the irradiation region LS on the following wiring pattern. For instance, the upper fuse 204 arranged immediately adjacent to the irradiation region LS of the upper fuse 204-1 in the width direction will not be the upper fuse 204-2 but rather the upper fuse 204-3 (q.v. sectional plane I-I′ in FIG. 2). Here, portions of the upper fuses 204 in two adjacent wiring patterns (except the irradiation regions LS) may overlap with each other in the width direction (q.v. sectional place II-II′ in FIG. 2). Since a structure in which the upper fuses 204 in two adjacent wiring patterns do not overlap with each other in the width direction at all will be described in the second embodiment, this embodiment will describe a situation in which portions of the upper fuses 204 in the adjacent wiring patterns (i.e., the connection portions of the contact plugs 203) overlap with each other in the width direction.

In this way, when each upper fuse 204 is disposed adjacent to another upper fuse 204 in the wiring pattern that follows the immediately adjacent wiring pattern in the width direction, an inter-wiring pattern distance will be defined based on an irradiation region LS and an upper fuse 204 disposed adjacent thereto in the width direction, and not based on adjacent wiring patterns. In other words, the inter-wiring pattern distance can be defined on the basis of every other wiring pattern in the width direction. For instance, in the case shown in FIG. 2, the distance between the upper fuses 204-1, 204-3 and 204-5 arranged on the upper side of the drawing should be set to an appropriate value such that a laser beam and the heat energy generated by the laser beam at the time of fusing will not influence (e.g. fuse) other upper fuses 204 (i.e., upper fuses 204 in wiring patterns following the immediately adjacent wiring pattern in the width direction). Likewise, for instance, in the case shown in FIG. 2, the distance between the upper fuses 204-2, 204-4 and 204-6 arranged on the upper side of the drawing should be set to an appropriate value such that a laser beam and the heat energy generated by the laser beam at the time of fusing will not influence (e.g. fuse) other upper fuses 204 (i.e., upper fuses 204 in wiring patterns following the immediately adjacent pattern in the width direction). In this description, such inter-wiring pattern distance will be referred to as a distance ‘a’.

In the meantime, from the design standpoint, the distance between each two adjacent wiring patterns (e.g. a wiring pattern including the upper fuse 204-1 and a wiring pattern including the upper fuse 204-2) should preferably be set to half the value of the distance ‘a’ (i.e., a/2).

With respect to the lower wiring layers 201, as shown in FIG. 2, they can be alternately arranged on the upper and lower portions thereof in a zigzag configuration corresponding to the positions of the upper fuses 204 as described above. Here, the layout of the lower wiring layers 201 is equivalent to the reverse of the layout of the upper fuses 204. For instance, as shown in FIG. 2, when the upper fuses 204-1, 204-3 and 204-5 are disposed on the upper level of the drawing and the rest of the upper fuses 204-2, 204-4 and 204-6 are disposed on the lower level, alternately, the lower wiring layers 201-1, 201-3 and 201-5 corresponding to the upper fuses 204-1, 204-3 and 204-5 on the upper stage will be disposed on the lower level, and the lower wiring layers 201-2, 201-4 and 201-6 corresponding to the upper fuses 204-2, 204-4 and 204-6 on the lower level will be disposed on the upper level.

Here, certain parts of corresponding upper fuse 204 and lower wiring layer 201 are overlapping and the interlayer insulation film 202 lies in between the two. In such overlapping portion, the contact plug 203 is formed as shown in FIG. 2, FIG. 3B and FIG. 4, and due to this contact plug 203, the upper fuse 204 and the lower wiring layer 201 are electrically connected. For instance, in a portion of the interlayer insulation film 202 where the corresponding upper fuse 204-1 and the lower wiring layer 201-1 are overlapping, the contact plug 203-1 is formed, and the upper fuse 204-1 and the lower wiring layer 201-1 are electrically connected via this contact plug 203-1.

Furthermore, the upper fuse 204 is covered with the upper layer protection film 205 as shown in FIG. 3A, FIG. 3B and FIG. 4. This upper layer protection film 205 should be adjusted to an appropriate thickness such that a laser beam can easily reach the wiring, and such that the wiring melted by the heat energy may be easily dispersed. Since the method for calculating the thickness of the upper layer protection film 205 is known, a detailed explanation thereof will be omitted here. Here, the upper layer protection film 205 may not only cover the surfaces of the upper fuses 204, but also the exposed portions of the interlayer insulation film 202, as shown in FIG. 3A and FIG. 3B.

The upper fuse 204 formed in the above-described way can be fused by irradiating the irradiation region LS with a laser beam using a laser repairing device (not shown).

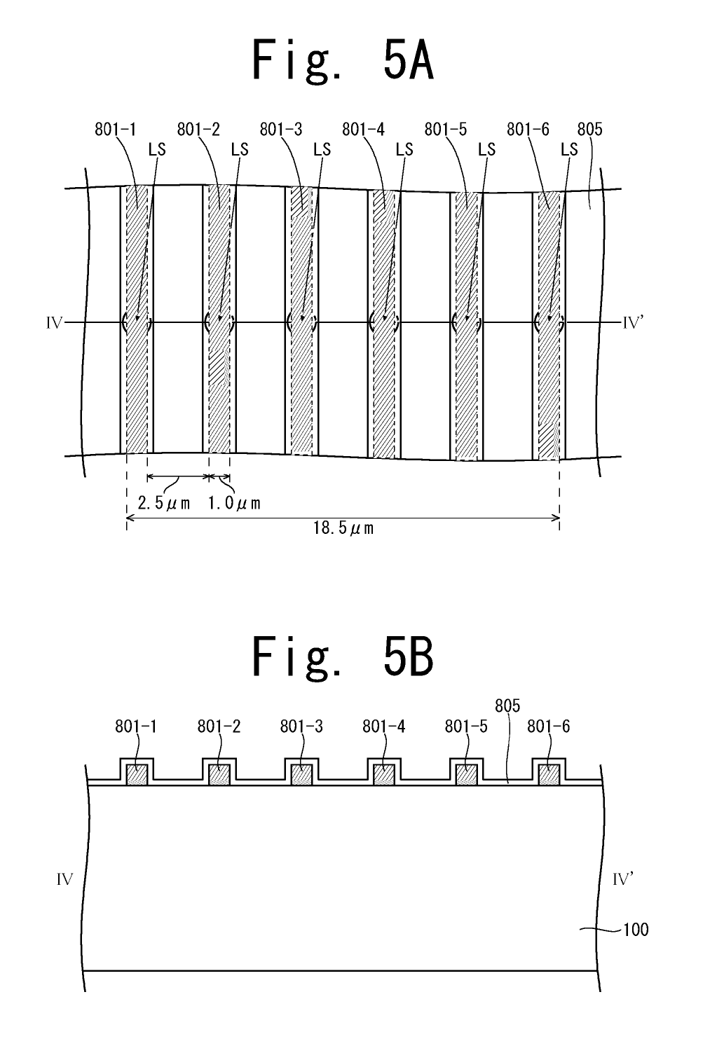

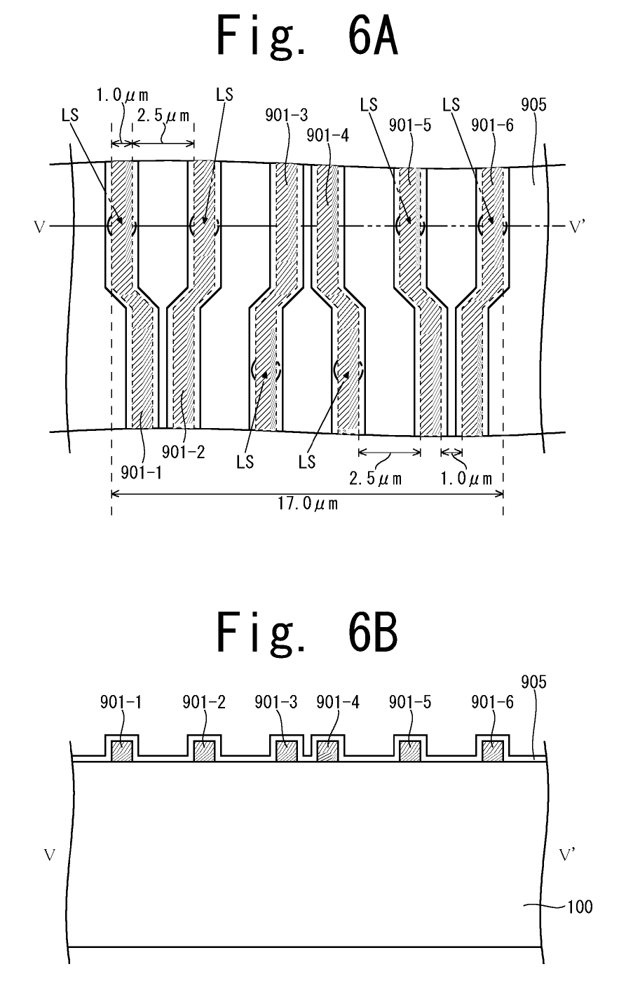

As described above, this embodiment has a structure in which, in a certain wiring pattern, at least a portion thereof adjacent to laser irradiation regions LS in other wiring patterns is moved to the lower layer in the layer structure. In other words, with respect to upper fuses in two adjacent wiring patterns, the upper fuses have certain regions which do not overlap with each other in the width direction. In the example shown in FIG. 2, for instance, each upper fuse 204 is disposed adjacent to another upper fuse 204 in a wiring pattern that follows the immediately adjacent wiring pattern in the width direction. Therefore, an inter-wiring pattern distance will be defined based on an irradiation region LS and an upper fuse 204 disposed next to it in the width direction, and not based on adjacent wiring patterns. In other words, the inter-wiring pattern distance can be defined on the basis of every other wiring pattern in the width direction. Therefore, according to this embodiment, it is possible to arrange the wiring patterns including the fuses at a greatly increased density (e.g. arranging the wiring patterns at smaller intervals). In the following, the effects of this embodiment will be described with reference to comparative examples 1 and 2 shown in FIG. 5 and FIG. 6.

FIG. 5A is a plan view showing the layout of fuses as a comparative example 1, and FIG. 5B is a sectional view of the layout shown in FIG. 5A taken along line IV-IV′.

As shown in FIG. 5A and FIG. 5B, a semiconductor memory device of the comparative example 1 has fuses 801-1 to 801-6, . . . (hereinafter an arbitrary fuse will be referred to as a fuse 801) formed on a lower substrate 100 (i.e., on an interlayer insulation film 108 to be precise), and an upper layer protection film 805 covering the fuses 801. Since the lower substrate 100 is the same as the lower substrate 100 shown in FIG. 3A, a detailed explanation thereof will be omitted here.

In the above structure, the fuses 801 have linear shapes. Therefore, the laser irradiation region LS of an arbitrary fuse 801 will be positioned close to the adjacent fuse 801. Here, with respect to two adjacent fuses 801, when one of them is to go through a laser repairing process, the other fuse 801 must not be influenced (e.g. fused) by the laser beam and the heat energy generated by the laser beam. Therefore, it is necessary to arrange the fuses 108 with an appropriate distance ‘a’ provided between each of the adjacent fuses 108.

FIG. 6A is a plan view showing a layout of fuses as a comparative example 2, and FIG. 6B is a sectional view of the layout shown in FIG. 6A taken along line V-V′.

As shown in FIG. 6A and FIG. 6B, a semiconductor memory device of the comparative example 2 has fuses 901-1 to 901-6, . . . (hereinafter an arbitrary fuse will be referred to as a fuse 901) formed on a lower substrate 100 (i.e., on an interlayer insulation film 108 to be precise), and an upper layer protection film 905 covering the fuses 901. Since the lower substrate 100 is the same as the lower substrate 100 shown in FIG. 3A, a detailed explanation thereof will be omitted here.

In the above structure, the fuses 901 have two linear portions connected in a zigzag shape, and an irradiation region LS is set on one of the two linear portions. Here, if two adjacent fuses 901 are considered as a pair, the linear portions of these fuses 901 where the irradiation regions LS are set are positioned on the same side (i.e., the upper or lower side in the drawing) while having an appropriate distance (‘a’) therebetween. On the other hand, the linear portions of these fuses 901 where the irradiation regions LS are not set are positioned close to each other in parallel. For instance, considering that the adjacent fuses 901-1 and 901-2 are a pair, the linear portions of these fuses 901-1 and 901-2 where the irradiation regions LS are set are positioned on the same side (i.e., the upper side in the drawing) while having an appropriate distance ‘a’ in between, and the linear portions of these fuses 901-1 and 901-2 where the irradiation regions LS are not set are positioned close to each other in parallel.

In the meantime, with respect to two adjacent pairs, the position of the linear portions where the irradiation regions LS are set and the position of the linear portions where the irradiation regions LS are not set in one pair of fuses 901 will be reversed in the other pair of fuses 901. For instance, referring to the pair of fuses 901-1 and 901-2 and the adjacent pair of fuses 901-3 and 901-4, the linear portions of the pair of fuses 901-1 and 901-2 where the irradiation regions LS are set are positioned on the upper side in FIG. 6A, and the linear portions of the pair of fuses 901-1 and 901-2 where the irradiation regions LS are not set are positioned on the lower side in FIG. 6A, whereas the linear portions of the adjacent pair of fuses 901-3 and 901-4 where the irradiation regions LS are set are positioned on the lower side in FIG. 6A and the linear portions of the pair of fuses 901-3 and 901-4 where the irradiation regions LS are not set are positioned on the upper side in FIG. 6A. Moreover, an appropriate distance ‘a’ is provided between two adjacent pairs having linear portions including the irradiation regions LS in one pair, and having linear portions not including the irradiation regions LS in the other pair.

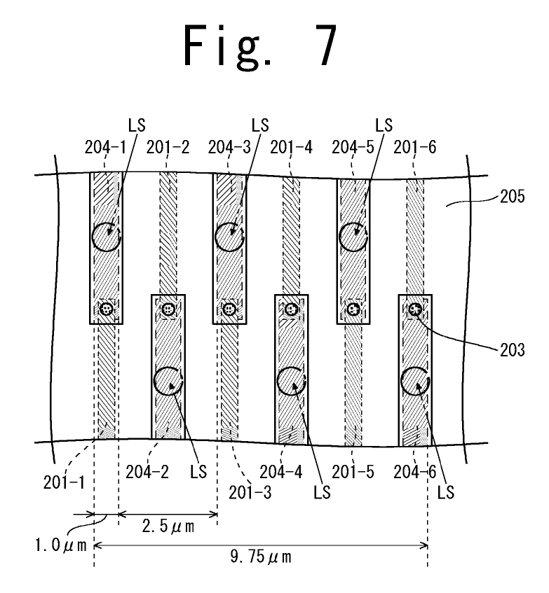

Note that it will be assumed that the widths of the upper fuse 204 of the first embodiment of the present invention, the fuse 801 of comparative example 1, and the fuse 901 of comparative example 2 are 1.0 μm, respectively, and the appropriate distance ‘a’ calculated based on this width and on the laser beam wavelength and energy is 2.5 μm. Under these conditions, with respect to comparative example 1, the total width of a layout including 6 fuses, as shown in FIG. 5A, will be 18.5 μm, and with respect to comparative example 2, the total width of a layout including 6 fuses, as shown in FIG. 6A, will be 17.0μm. On the other hand, with respect to the first embodiment of the present invention, the total width of a layout including 6 fuses, as shown in FIG. 7, will be 9.75 μm.

Furthermore, under these conditions, if the memory cells are disposed at a 0.64 μm cycle, for instance, the fuses 801 can be disposed at a ratio of 6 fuses for each 28 (=18.5[μm]/0.64[μm]) memory cells in comparative example 1, the fuses 901 can be disposed at a ratio of 6 fuses for each 26 (=17.0[μm]/0.64[μm]) memory cells in comparative example 2, and the upper fuses 204 can be disposed at a ratio of 6 upper fuses for each 15 (=9.75[μm]/0.64[μm]) memory cells in the first embodiment.

Moreover, under the same conditions, if the memory cells are disposed at a 0.32 μm cycle, for instance, the fuses 801 can be disposed at a ratio of 6 fuses for each 57 (=18.5[μm]/0.32[μm]) memory cells in comparative example 1, the fuses 901 can be disposed at a ratio of 6 fuses for each 53 (=17.0[μm]/0.32[μm]) memory cells in comparative example 2, and the upper fuses 204 can be disposed at a ratio of 6 upper fuses for each 30 (=9.75[μm]/0.32[μm]) memory cells in the first embodiment. These evaluations are shown in chart 1 provided below.

CHART 1

| | COMPARATIVE | COMPARATIVE | FIRST |
|---|---|---|---|
| | EXAMPLE 1 | EXAMPLE 2 | EMBODIMENT |
| 0.64 μm | 6 FUSES/ | 6 FUSES/ | 6 FUSES/ |
| CYCLE | 28 CELLS | 26 CELLS | 15 CELLS |
| 0.32 μm | 6 FUSES/ | 6 FUSES/ | 6 FUSES/ |
| CYCLE | 57 CELLS | 53 CELLS | 30 CELLS |

As can be seen from the above description and chart 1, according to the first embodiment of the present invention, it is possible to greatly reduce the width between wiring patterns including fuses (i.e., upper fuses), and therefore, it is possible to increase the number of fuses to be mounted on the semiconductor memory device 1. As a result, in the first embodiment of the present invention, it is possible to increase the ratio of salvable memory cells and improve the yield ratio of the product.

In the embodiment of the present invention described with reference to FIG. 5 to FIG. 7, when the number of fuses/upper fuses is set to 6, it is possible to decrease the number of memory cells to be redressed by 53% to 54% as compared to comparative examples 1 and 2. In other words, in this embodiment, it is possible to arrange about twice as many fuses/upper fuses in the same area, as compared to comparative examples 1 and 2, for instance.

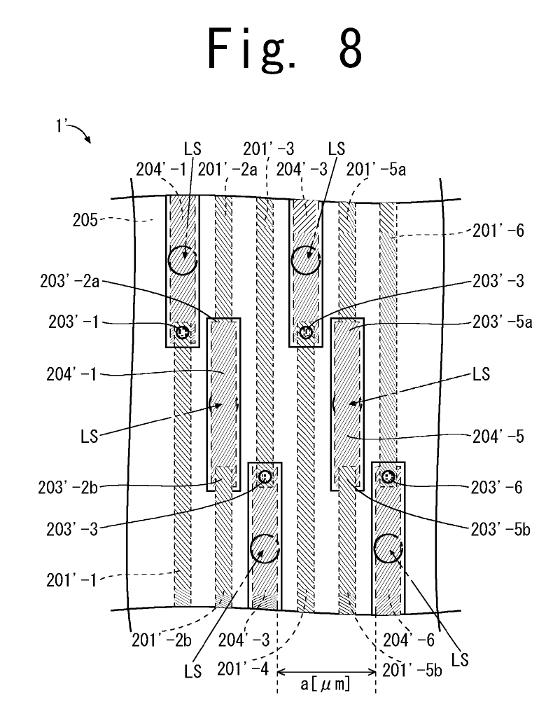

In the case described above, the irradiation regions LS are arranged in two rows in the width direction of the upper fuses 204 (q.v. FIG. 2). However, the present invention is not limited to this condition, and it is also possible to have the irradiation regions LS arranged in three rows in the width direction of the upper fuses 204. For instance, FIG. 8 shows a structure in which the irradiation regions LS are arranged in three rows in the width direction of the upper fuses 204.

In a semiconductor memory device 1′ shown in FIG. 8, the lower wiring layers 201-1 to 201-6, . . . in the semiconductor memory device 1 are replaced with lower wiring layers 201′-1 to 201′-6, . . . (hereinafter an arbitrary lower wiring layer will be referred to as a lower wiring layer 201′), the upper layer wiring layers 204-1 to 204-6, . . . in the semiconductor memory device 1 are replaced with upper layer wiring layers 204′-1 to 204′-6, . . . (hereinafter an arbitrary upper layer wiring layer will be referred to as an upper layer wiring layer 204′), and the contact plugs 203-1 to 203-6, . . . in the semiconductor device 1 are replaced with contact plugs 203′-1 to 203′-6, . . . (hereinafter an arbitrary contact plug will be referred to as a contact plug 203′). The rest of the structure in the semiconductor memory device 1′ is the same as the semiconductor memory device 1 (q.v. FIG. 2), and therefore, a detailed description thereof will be omitted here.

As shown in FIG. 8, when the irradiation regions LS are arranged in three rows in the width direction of the upper fuses 204′, an inter-wiring pattern distance will be defined based on an irradiation region LS and an upper fuse 204′ disposed next to it in the width direction, and not based on adjacent wiring patterns. Therefore, the inter-wiring pattern distance can be defined on the basis of every two wiring patterns having two other wiring patterns therebetween. By such arrangement, it is possible to arrange the wiring patterns including the fuses at a greatly increased density (e.g. arranging the wiring patterns at smaller intervals).

Likewise, when the irradiation regions LS are arranged in ‘n’ (n is an integer equal to or greater than 4) rows in the width direction of the upper fuse 204, for instance, an inter-wiring pattern distance will be defined based on an irradiation region LS and an upper fuse 204 disposed next to it in the width direction, and not based on adjacent wiring patterns. Therefore, the inter-wiring pattern distance can be defined on the basis of every two wiring patterns having ‘n−1’ other wiring patterns therebetween. By such arrangement, it is possible to arrange the wiring patterns including the fuses at a greatly increased density (e.g. arranging the wiring patterns at smaller intervals).

### Embodiment 2

Next, a second embodiment of the present invention will be described in detail with reference to the drawings. In the following, the same reference numbers will be used for the structures that are the same as the first embodiment, and redundant explanations of those structural elements will be omitted.

This embodiment will show a structure of a semiconductor memory device in which, in a certain wiring pattern including a fuse, at least a laser irradiation region is placed on the upper layer and the other regions are moved to a lower layer in the layer structure.

Structure

The structure of the semiconductor memory device 2 according to this embodiment is the same as the semiconductor device 1 according to the first embodiment, and redundant explanations thereof will be omitted here.

Sectional Structure

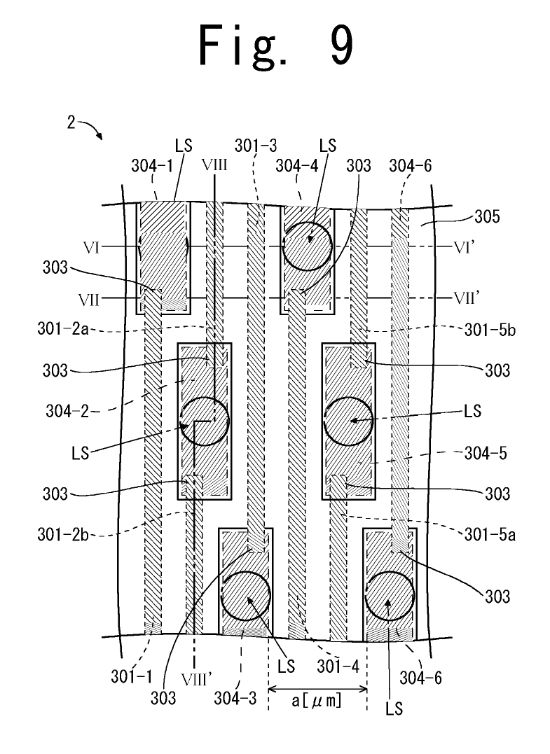

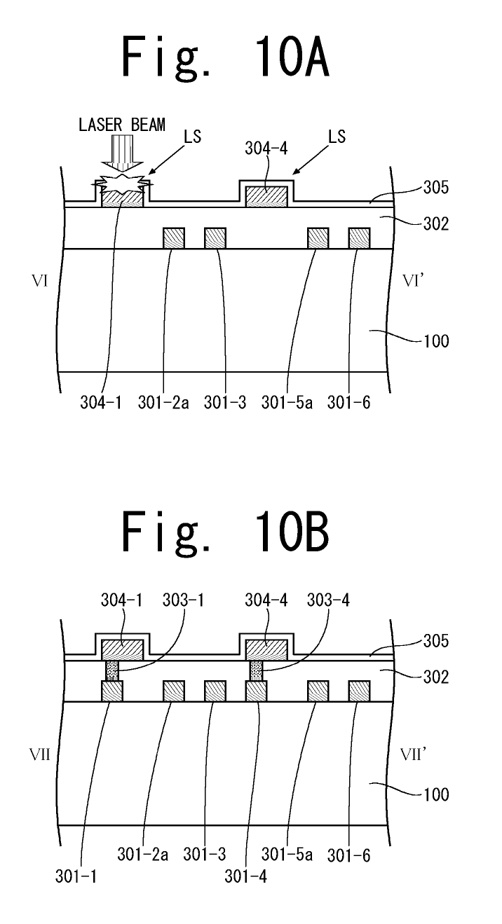

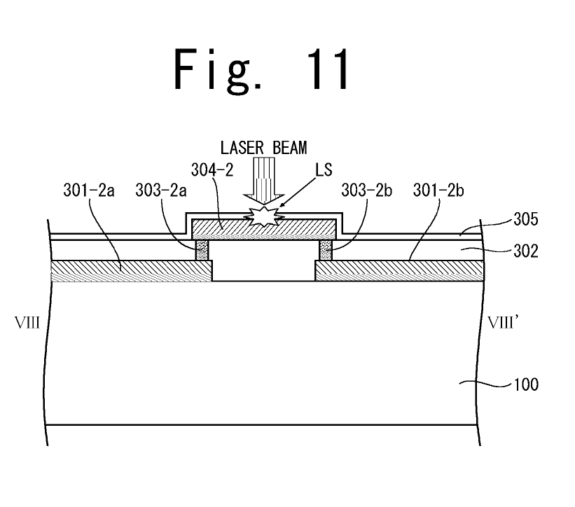

Now, the layer structure of the semiconductor memory device 2 according to the second embodiment of the present invention will be described in detail with reference to the drawings. FIG. 9 is a plan view showing the layer structure of the semiconductor memory device 2, and shows a portion extracted from a region where fuses are arranged (i.e., a portion corresponding to the fuse portion 24 of the redundancy determination circuit 20 shown in FIG. 1). FIG. 10A is a sectional view of the semiconductor memory device 2 shown in FIG. 9 taken along line VI-VI′, FIG. 10B is a sectional view of the semiconductor memory device 2 shown in FIG. 9 taken along line VII-VII′, and FIG. 11 is a sectional view of the semiconductor memory device 2 shown in FIG. 9 taken along line VIII-VIII′. In FIG. 10A, FIG. 10B and FIG. 11, since the lower substrate 100 is the same as the first embodiment (q.v., FIG. 3A), the structure of the lower substrate 100 is shown in a simplified form.

As shown in FIG. 10A, FIG. 10B and FIG. 11, the semiconductor memory device 2 has a lower substrate 100, a wiring layer 110 formed on the lower substrate 100, a lower wiring layers (i.e., first to third wiring layers) 301-1 to 301-6, . . . (hereinafter an arbitrary lower wiring layer will be referred to as a lower wiring layer 301) also formed on the lower substrate 100, an interlayer insulation film 302 formed so as to bury the lower wiring layer 301, upper fuses (i.e., first to third fuses) 304-1 to 304-6, . . . (hereinafter an arbitrary upper fuse will be referred to as an upper fuse 304) formed on the interlayer insulation film 302, contact plugs (i.e., first to third contact plugs) 303-1 to 303-6, . . . (hereinafter an arbitrary contact plug will be referred to as a contact plug 303) electrically connecting the lower wiring layers 301 and the upper fuses 304, and an upper layer protection film 305 covering the upper fuses 304.

In the above structure, the lower wiring layer 301 and the upper fuse 304 correspond to each other, and by having them electrically connected via the contact plug 303 as shown in FIG. 10B and FIG. 11, one wiring pattern is formed. For instance, the lower wiring layer 301-1 and the upper fuse 304-1 correspond to each other, and by having them electrically connected via the contact plug 303-1, one wiring pattern is formed. Likewise, for instance, the lower wiring layers 301-2a and 301-2b and the upper fuse 304-2 correspond to each other, and by having them electrically connected via the contact plugs 303-2a and 302-2b, one wiring pattern is formed.

The lower wiring layer 301 is a conductive film made of, for example, polysilicon (Poly-Si), polycide (e.g., tungsten polycide (WSi/Poly-Si)), etc. This type of lower wiring layer 301 can be formed using a known patterning technology (i.e., photolithography and etching), for instance. Here, the wiring layer 110 and the lower wiring layer 301 may be electrically connected.

The wiring layer 110 and the lower wiring layer 301 formed on the interlayer insulation film 108 are buried in the intermediate insulation layer 302. In other words, the interlayer insulation film 302 is formed on the interlayer insulation film 108 to a thickness sufficient to bury the wiring layer 110 and the lower wiring layer 301. This interlayer insulation film 302 is a type of insulation film formed by depositing silicon oxide (SiOx) using a CVD method, for instance. Here, a surface of the interlayer insulation film 302 should preferably be planarized using a CMP method, for instance.

In the interlayer insulation film 302, multiple openings are formed corresponding with the positions of the lower wiring layers 301 using the known photolithography and etching processes. These openings are filled up with a conductive material such as tungsten (W), copper (Cu) or the like, to become the contact plugs 303. The contact plugs 303 are formed by filling the openings with tungsten (W), etc. using a CVD method or filling the openings with copper (Cu), etc. using a plating method, for instance.

On the interlayer insulation film 302, the upper fuses 304 are formed corresponding with the positions of the contact plugs 303. These upper fuses 304 are conductive films made of polysilicon, polycide, etc., for instance, and can be formed using a known patterning technology (i.e., photolithography and etching).

The upper fuses 304 formed in the above described way are covered with the upper layer protection film 305. This upper layer protection film 305 is also formed on the exposed portions of the interlayer insulation film 302. The upper layer protection film 305 is a type of insulation film formed as a P-TEOS film using a plasma CVD method, for instance, and it functions as a film for protecting the upper fuses 304 from dust, dirt, physical or electrical damage, laser beams irradiating other upper fuses 304, and the heat energy generated by the laser irradiation. The upper layer protection film 305 should be adjusted to an appropriate thickness such that a laser beam can easily reach the wiring and such that the wiring melted by the heat energy may be easily dispersed, when the laser repairing method is used.

In the above structure, as with the first embodiment, the wiring pattern including the lower wiring layer 301, the upper fuse 304, and the contact plug 303 constitutes the fuse portion 24 contained in the redundancy determination circuit 20 shown in FIG. 1. This type of wiring pattern is formed as a part of a wiring that connects a circuit (not shown) provided in the redundancy determination circuit 20 in order to determine whether or not redressing is necessary, with the redundant row decoder 21 disposed at a subsequent level of the redundancy determination circuit 20.

Layout of Wiring Patterns

Now, with reference to FIG. 9 to FIG. 11, the layout of wiring patterns which each include the lower wiring layer 301, the upper fuse 304, and the contact plug 303 will be described.

As described with reference to FIG. 10A, FIG. 10B and FIG. 11, each individual wiring pattern has a structure in which the lower wiring layer 301 formed on the lower substrate 100 (i.e., a lower layer) and the upper fuse 304 formed on the interlayer insulation film 302 (i.e., an upper layer) are connected via the contact plug 303 formed within the interlayer insulation film 302. This is a structure in which, in a certain wiring pattern, at least a laser irradiation region LS is placed on the upper layer and the other regions are moved to a lower layer in the layer structure.

In the layout example shown in FIG. 9, laser irradiation regions LS are arranged perpendicular to the direction (i.e., the vertical direction in FIG. 9) in which the wiring patterns extend (i.e., the laser irradiation regions LS are arranged in the horizontal direction in FIG. 2) in three upper and lower rows in the drawing. The irradiation regions LS in the wiring patterns are alternately arranged on the upper, middle, and lower portions of the wiring patterns in the drawing. Along with that, the upper fuses 304 in the wiring patterns are also alternately arranged on the upper, middle, and lower portions of the wiring patterns. Therefore, considering an irradiation region LS of a certain upper fuse 304 in a certain wiring pattern, an upper fuse 304 arranged immediately adjacent to this irradiation region LS in a width direction will not be the irradiation regions LS on the next two adjacent wiring patterns but rather the irradiation region LS that is after the next two adjacent wiring patterns. For instance, the upper fuse 304 arranged immediately adjacent to an irradiation region LS of the upper fuse 304-1 in the width direction will not be the upper fuses 304-2 and 304-3 but rather the upper fuse 304-4. Here, the upper fuses 304 in two adjacent wiring patterns should not completely overlap with each other in the width direction (q.v. sectional plane VII-VII′ in FIG. 9).

In this way, when each upper fuse 304 is disposed adjacent to another upper fuse 304 in the wiring pattern that follows the two immediately adjacent wiring patterns in the width direction, an inter-wiring pattern distance will be defined based on an irradiation region LS and an upper fuse 304 disposed next to it in the width direction, and not based on adjacent wiring patterns. In other words, the inter-wiring pattern distance can be defined on the basis of every third wiring pattern in the width direction. For instance, in the case shown in FIG. 9, the distance ‘a’ between the upper fuses 304-1 and 304-4 arranged on the upper side of the drawing should be set to an appropriate value such that a laser beam and the heat energy generated by the laser beam at the time of fusing will not influence (e.g. fuse) other upper fuses 304 (i.e., upper fuses 304 in the two adjacent wiring patterns in the width direction). Likewise, for instance, in the case shown in FIG. 9, the distance ‘a’ between the upper fuses 304-2 and 304-5 arranged on the upper side of the drawing should be set to an appropriate value such that a laser beam and the heat energy generated by the laser beam at the time of fusing will not influence (e.g. fuse) other upper fuses 304 (i.e., upper fuses 304 in the two adjacent wiring patterns in the width direction), and the distance ‘a’ between the upper fuses 304-3 and 304-6 arranged on the upper side of the drawing should be set to an appropriate value such that a laser beam and the heat energy generated by the laser beam at the time of fusing will not influence (e.g. fuse) other upper fuses 304 (i.e., upper fuses 304 in the two adjacent wiring patterns in the width direction).

In the meantime, from the design standpoint, the distance between each two adjacent wiring patterns (e.g. a wiring pattern including the upper fuse 304-1 and a wiring pattern including the upper fuse 304-2) should preferably be set to one third of the value of the distance ‘a’ (i.e., a/3).

With respect to the lower wiring layers 301, as shown in FIG. 9, they can be alternately arranged so that their presence and absence is reversed so as to correspond to the positions of the upper fuses 304 as described above. For instance, as shown in FIG. 9, when the upper fuses 304-1 and 304-4 are disposed on the upper level in the drawing, the upper fuses 304-3 and 304-6 are disposed on the lower level and the rest of the upper fuses 304-2 and 304-5 are disposed on the middle level, alternately, the lower wiring layers 301-1 and 301-4 corresponding to the upper fuses 304-1 and 304-4 on the upper level will be disposed on the lower level, the lower wiring layers 301-3 and 301-6 corresponding to the upper fuses 304-3 and 304-6 on the lower level will be disposed on the upper level, and the lower wiring layers 301-2a, 301-2b, 301-5a and 301-5b corresponding to the upper fuses 304-2 and 304-5 on the middle level will be disposed on the upper and lower level.

Here, certain parts of corresponding upper fuse 304 and lower wiring layer 301 are overlapping and the interlayer insulation film 302 lies in between the two. In such overlapping portion, the contact plug 303 is formed as shown in FIG. 9, FIG. 10B and FIG. 11, and due to this contact plug 303, the upper fuse 304 and the lower wiring layer 301 are electrically connected. For instance, in a portion of the interlayer insulation film 302 where the corresponding upper fuse 304-1 and the lower wiring layer 301-1 are overlapping, the contact plug 303-1 is formed, and the upper fuse 304-1 and the lower wiring layer 301-1 are electrically connected via this contact plug 303-1. Furthermore, for instance, in a part of interlayer insulation film 302 where the corresponding upper fuse 304-2a/304-2b and the lower wiring layer 301-2 are overlapping, the contact plug 303-2a/303-2b is being formed, and the upper fuse 304-2 and the lower wiring layer 301-2 are electrically connected via this contact plug 303-2a/303-2b.

Furthermore, the upper fuse 304 is covered with the upper layer protection film 305 as shown in FIG. 10A, FIG. 10B and FIG. 11. This upper layer protection film 305 should be adjusted to an appropriate thickness such that a laser beam can easily reach the wiring and such that the wiring melted by the heat energy may be easily dispersed. Since the method for calculating the thickness of the upper layer protection film 305 is known, a detailed explanation thereof will be omitted here. Here, the upper layer protection film 305 may not only cover the surfaces of the upper fuses 304 but also the exposed portions of the interlayer insulation film 302, as shown in FIG. 10A and FIG. 10B.

The upper fuse 304 formed in the above-described way can be fused by irradiating the irradiation region LS with a laser beam using a laser repairing device (not shown).

As described above, this embodiment has a structure in which, in a certain wiring pattern, at least a laser irradiation region LS is drawn up to the upper layer in the layer structure, and the other portions (i.e., wiring portions) are moved to the lower layer in the layer structure. In other words, with respect to upper fuses in two adjacent wiring patterns, the upper fuses will not overlap with each other in the width direction at all. In the example shown in FIG. 9, for instance, each upper fuse 304 is disposed adjacent to another upper fuse 304 in a wiring pattern that follows the two immediately adjacent wiring patterns in the width direction. Therefore, an inter-wiring pattern distance will be defined based on an irradiation region LS and an upper fuse 304 disposed next to it in the width direction, and not based on adjacent wiring patterns. In other words, in the example shown in FIG. 9, the inter-wiring pattern distance can be defined on the basis of two wiring patterns having two other wiring patterns therebetween in the width direction. Therefore, according to this embodiment, it is possible to arrange the wiring patterns including the fuses at a greatly increased density (e.g. arranging the wiring patterns at smaller intervals). In the following, the effects of this embodiment will be described with reference to comparative examples 1 and 2 shown in FIG. 5 and FIG. 6 that were used in the first embodiment as well.

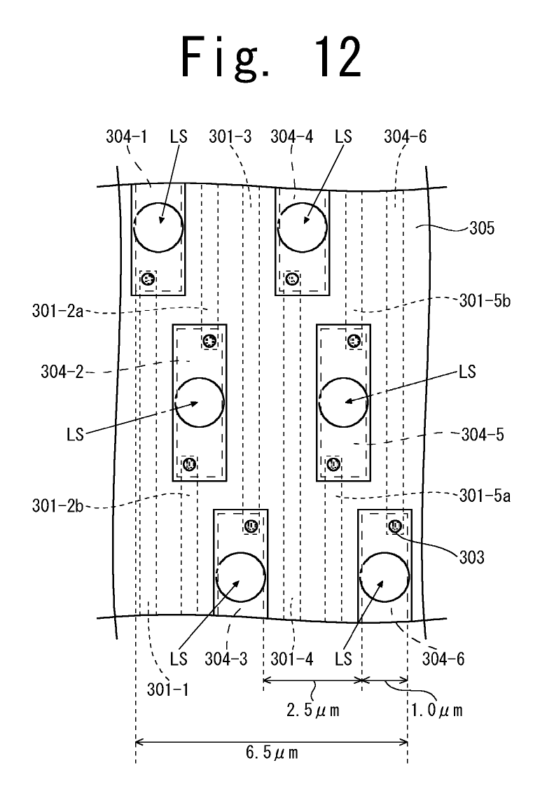

Note that, as in the first embodiment, it will be assumed that the widths of the upper fuse 304 of the second embodiment of the present invention, the fuse 801 of comparative example 1, and the fuse 901 of the comparative example 2 are 1.0 μm, respectively, and the appropriate distance ‘a’ calculated based on this width and on the laser beam wavelength and energy is 2.5 μm. Under these conditions, with respect to comparative example 1, the total width of a layout including 6 fuses, as shown in FIG. 5A, will be 18.5 μm, and with respect to comparative example 2, the total width of a layout including 6 fuses, as shown in FIG. 6A, will be 17.0 μm. On the other hand, with respect to the first embodiment of the present invention, the total width of a layout including 6 fuses, as shown in FIG. 12, will be 6.5 μm.

Furthermore, under these conditions, if the memory cells are disposed at a 0.64 μm cycle, for instance, the fuses 801 can be disposed at a ratio of 6 fuses for each 28 (=18.5[μm]/0.64[μm]) memory cells in comparative example 1, the fuses 901 can be disposed at a ratio of 6 fuses for each 26 (=17.0[μm]/0.64[μm]) memory cells in comparative example 2, and the upper fuses 304 can be disposed at a ratio of 6 upper fuses for each 6 (=6.5[μm]/0.64[μm]) memory cells in the second embodiment.

Moreover, under the same conditions, if the memory cells are disposed at a 0.32 μm cycle, for instance, the fuses 801 can be disposed at a ratio of 6 fuses for each 57 (=18.5[μm]/0.32[μm]) memory cells in comparative example 1, the fuses 901 can be disposed at a ration of 6 fuses for each 53 (=17.0[μm]/0.32[μm]) memory cells in comparative example 2, and the upper fuses 304 can be disposed at a ration of 6 upper fuses for each 20 (=6.5[μm]/0.32[μm]) memory cells in the second embodiment. These evaluations are shown in chart 2 provided below.

CHART 2

| | COMPARATIVE | COMPARATIVE | SECOND |
|---|---|---|---|
| | EXAMPLE 1 | EXAMPLE 2 | EMBODIMENT |
| 0.64 μm | 6 FUSES/ | 6 FUSES/ | 6 FUSES/ |
| CYCLE | 28 CELLS | 26 CELLS | 10 CELLS |
| 0.32 μm | 6 FUSES/ | 6 FUSES/ | 6 FUSES/ |
| CYCLE | 57 CELLS | 53 CELLS | 20 CELLS |

As can be seen from the above description and chart 2, according to the second embodiment of the present invention, it is possible to greatly reduce the width between wiring patterns that include fuses (i.e., upper fuses), and therefore, it possible to increase the number of fuses to be mounted on the semiconductor memory device 2. As a result, in the second embodiment of the present invention, it is possible to increase the ratio of salvable memory cells and improve the yield ratio of the product.

In the embodiment of the present invention described with reference to FIG. 9 to FIG. 12, when the number of fuses/upper fuses is set to 6, it is possible to decrease the number of memory cells to be redressed by 35% to 36% as compared to comparative examples 1 and 2. In other words, in this embodiment, it is possible to arrange about three times as many fuses/upper fuses in the same area, as compared to comparative examples 1 and 2, for instance.

In the case described above, the irradiation regions LS are arranged in three rows in the width direction of the upper fuses 304 (q.v. FIG. 9). However, the present invention is not limited to this condition, and it is also possible to have the irradiation regions LS arranged in two rows or four or more rows in the width direction of the upper fuses 304.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2005-173350. The entire disclosures of Japanese Patent Application No. 2005-173350 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

What is claimed is:

1. A semiconductor device comprising:
a lower substrate;
an interlayer insulation film formed on the lower substrate;
a first wiring pattern having a first wiring layer formed on the lower substrate, a first fuse formed on the interlayer insulation film, and a first contact plug electrically connected between the first wiring layer and first fuse; and
a second wiring pattern having a second wiring layer, a second fuse formed on the interlayer insulation film, and a second contact plug electrically connected between the second wiring layer and the second fuse, the second fuse having a region which does not overlap with the first fuse in a width direction, the second wiring pattern being separated from the first wiring pattern by a predetermined distance, and the first fuse having a region which does not overlap with the second fuse in a width direction.

2. A semiconductor device comprising:
a lower substrate;
an interlayer insulation film formed on the lower substrate;
a first wiring pattern having a first wiring layer formed on the lower substrate, a first fuse formed on the interlayer insulation film, and a first contact plug electrically connected between the first wiring layer and first fuse; and
a second wiring pattern having a second wiring layer, a second fuse formed on the interlayer insulation film, and a second contact plug electrically connected between the second wiring layer and the second fuse, the second fuse not overlapping with the first fuse in a width direction, the second wiring pattern being separated from the first wiring pattern by a predetermined distance.

3. The semiconductor device according to claim 2, further comprising:
a third wiring pattern having a third wiring layer formed on the lower substrate, a third fuse formed on the interlayer insulation film, a third contact plug electrically connected between the third wiring layer and the third fuse, the third fuse not overlapping with the first and second fuses in the width direction, the third wiring pattern being separated from the second wiring pattern by the predetermined distance.

4. The semiconductor device according to claim 3, wherein
the first to third wiring patterns are arranged alternately in the width direction at intervals.

5. The semiconductor device according to claim 1, wherein
the first and second wiring patterns are arranged alternately in the width direction, and
the first and second fuses of the first and second wiring patterns are arranged alternately in a zigzag configuration.

6. The semiconductor device according to claim 2, wherein
the first and second wiring patterns are arranged alternately in the width direction, and
the first and second fuses of the first and second wiring patterns are arranged alternately in a zigzag configuration.

7. The semiconductor device according to claim 1, wherein
the first and second wiring patterns are arranged alternately in the width direction, and
the first fuse is separated from the second fuse by a predetermined distance such that the first fuse will not be influenced by fusing of the second fuse.

8. The semiconductor device according to claim 2, wherein
the first and second wiring patterns are arranged alternately in the width direction, and
the first fuse is separated from the second fuse by a predetermined distance such that the first fuse will not be influenced by fusing of the second fuse.

9. The semiconductor device according to claim 7, wherein
the first and second fuses include polysilicon or polycide.

10. The semiconductor device according to claim 8, wherein
the first and second fuses include polysilicon or polycide.

11. The semiconductor device according to claim 1, wherein
the second wiring pattern is arranged at a midpoint between two first wiring patterns which are adjacent in the width direction.

12. The semiconductor device according to claim 2, wherein
the second wiring pattern is arranged at a midpoint between two first wiring patterns which are adjacent in the width direction.

13. The semiconductor device according to claim 1, further comprising:
a protective film covering the first and second fuses, respectively.

14. The semiconductor device according to claim 2, further comprising:
a protective film covering the first and second fuses, respectively.

15. The semiconductor device according to claim 1, further comprising:
a memory cell array comprising a plurality of memory cells that are connected to word lines;
a redundant memory cell array comprising a plurality of redundant memory cells that are connected to redundant word lines;
a word line driver configured to drive the word line that is connected to the memory cell corresponding to an inputted address;
a redundancy determination circuit comprising the first wiring pattern and second wiring pattern, and configured to determine whether or not a redundant memory cell should be used based on the inputted address; and
a redundant word line driver configured to drive the redundant word line that is connected to the redundant memory cell in order to recover the memory cell corresponding to the inputted address if the redundancy determination circuit determines that the redundant memory cell should be used.

16. The semiconductor device according to claim 2, further comprising:
a memory cell array comprising a plurality of memory cells that are connected to word lines;
a redundant memory cell array comprising a plurality of redundant memory cells that are connected to redundant word lines;
a word line driver configured to drive the word line that is connected to the memory cell corresponding to an inputted address;
a redundancy determination circuit comprising the first wiring pattern and second wiring pattern, and configured to determine whether a redundant memory cell should be used or not based on the inputted address; and
a redundant word line driver configured to drive the redundant word line that is connected to the redundant memory cell in order to recover the memory cell corresponding to the inputted address if the redundancy determination circuit determines that the redundant memory cell should be used.
